(19) United States
(12) Patent Application Publication
(10) Pub. No.: US 2014/0360246 A1
(43) Pub. Date: Dec. 11, 2014

(54) MICRO-ELECTRO-MECHANICAL-SYSTEM RESONANT SENSOR AND METHOD OF CONTROLLING THE SAME

(71) Applicant: Hyundai Motor Company, Seoul (KR)

(72) Inventors: Soon-myung Kwon, Seoul (KR); Sang Gyu Park, Seoul (KR)

(73) Assignee: Hyundai Motor Company, Seoul (KR)

(21) Appl. No.: 14/092,202

(22) Filed: Nov. 27, 2013

(30) Foreign Application Priority Data
Jun. 7, 2013 (KR) 10-2013-0065508

(51) Int. Cl. B81B 7/00

(52) U.S. Cl. CPC B81B 7/008
USPC 73/1.82

(57) ABSTRACT

A micro-electro-mechanical-system (MEMS) resonant sensor includes: a MEMS unit that generates an output signal corresponding to a vibration component of a mass body vibratable between a first driving electrode and a second driving electrode; an automatic gain control (AGC) unit that automatically generates a comparative voltage by controlling a gain of the output signal; and a bias unit that receives a reference voltage and generates a bias voltage using the comparative voltage and the reference voltage, wherein a sinusoidal driving voltage is applied to the first driving electrode and the second driving electrode, and the bias voltage is applied to the mass body. It can maintain the amplitude of the mass body stably in the MEMS resonant sensor, and prevent malfunction of an electronic circuit by reducing a response error of the MEMS resonant sensor.

### CROSS-REFERENCE TO RELATED APPLICATION

The present application claims priority to Korean Patent Application No. 10-2013-0065508 filed on Jun. 7, 2013, the entire contents of which is incorporated herein for all purposes by this reference.

### BACKGROUND OF THE INVENTION

1. Field of the Invention

The present invention relates to a micro-electro-mechanical-system (MEMS) resonant sensor and a method of controlling the MEMS resonant sensor.

2. Description of Related Art

A resonant sensor calculates a size of a physical quantity input by detecting a resonant characteristic that is changed by applying a physical quantity from the outside. A resonant sensor is generally used as a MEMS resonant sensor because of its wide input range and easy connection through a digital interface.

The MEMS resonant sensor is modeled by a mass body-spring-damper, and detects a resonant characteristic such as amplitude of the mass body by applying a physical quantity from the outside and a conversion coefficient of resonant frequency. The mass body of the MEMS resonant sensor vibrates by repeating a resonant loop consisted of three parts: the mass body of the MEMS resonant sensor vibrates initially and precisely by applying the physical quantity from the outside; a signal of initial vibration amplifies through an amplifier and generates an electrostatic force; and the mass body will have a broader amplitude according to the electrostatic force.

Meanwhile, the MEMS resonant sensor can lead to a spring constant error or an amplifier gain error due to a process error of the mass body or an amplifier error of the resonant loop. Thus, a problem such as an irregular amplitude of the mass body occurs. This problem becomes a response error of the MEMS resonant sensor, and it leads to malfunction of an electronic circuit.

The information disclosed in this Background of the Invention section is only for enhancement of understanding of the general background of the invention and should not be taken as an acknowledgement or any form of suggestion that this information forms the prior art already known to a person skilled in the art.

### BRIEF SUMMARY

Various aspects of the present invention are directed to providing a MEMS resonant sensor and a method of controlling the same having advantages of stable maintenance of the amplitude of the mass body.

In an aspect of the present invention, a micro-electro-mechanical-system (MEMS) resonant sensor may include a MEMS unit that generates an output signal corresponding to a vibration component of a mass body vibratable between a first driving electrode and a second driving electrode, an automatic gain control (AGC) unit that generates a comparative voltage by automatically controlling a gain of the output signal of the MEMS unit, and a bias unit that receives the comparative voltage and a reference voltage and generates a bias voltage using the comparative voltage and the reference voltage, wherein a sinusoidal driving voltage is applied to the first driving electrode and the second driving electrode, and the bias voltage is applied to the mass body.

The MEMS resonant sensor may further include a hold amplifier generating an input signal that is input to the MEMS unit by amplifying the output signal of the MEMS unit.

The bias unit generates a sum or a difference of the reference voltage and the comparative voltage as the bias voltage.

Another exemplary embodiment of the present invention provides a method of controlling a MEMS resonant sensor using a mass body vibratable by an electrostatic force between a first driving electrode and a second driving electrode, including generating an output signal corresponding to a vibration component of the mass body, generating a comparative voltage corresponding to the output signal by automatically controlling the gain of the output signal, adjusting a level of a bias voltage applied to the mass body by using a reference voltage and the comparative voltage, and controlling the electrostatic force by applying the adjusted bias voltage to the mass body.

The generation of the comparative voltage corresponding to the output signal may include applying a sinusoidal driving voltage to the first driving electrode and the second driving electrode. The generation of the comparative voltage corresponding to the output signal by automatically controlling the gain of the output signal may include generating a sum or a difference of the reference voltage and the comparative voltage as the bias voltage.

Yet another embodiment of the present invention provides a method of controlling a MEMS resonant sensor, including applying a sinusoidal driving voltage to a first driving electrode and a second driving electrode, applying a bias voltage to a mass body which vibrates in a first direction between the first driving electrode and the second driving electrode by an electrostatic force, generating an output signal corresponding to a vibration component of the mass body, and calculating a size of a physical quantity input from the outside in a second direction by detecting the output signal, wherein the applying the bias voltage to the mass body may include generating a comparative voltage corresponding to the output signal by automatically controlling the gain of the output signal, adjusting a level of the bias voltage applied to the mass body by using a reference voltage and the comparative voltage, and controlling the electrostatic force by applying the adjusted bias voltage to the mass body.

The generation of the comparative voltage corresponding to the output signal by automatically controlling the gain of the output signal may include generating a sum or a difference of the reference voltage and the comparative voltage as the bias voltage.

According to the present invention, the amplitude of a mass body can be stably maintained in a MEMS resonant sensor, and a malfunction of an electronic circuit can be prevented by reducing a response error of the MEMS resonant sensor.

In addition, a rising time of the mass body whose amplitude is in an initial weak condition in the MEMS resonant sensor can be considerably reduced.

The methods and apparatuses of the present invention have other features and advantages which will be apparent from or are set forth in more detail in the accompanying drawings, which are incorporated herein, and the following Detailed Description, which together serve to explain certain principles of the present invention.

### BRIEF DESCRIPTION OF THE DRAWINGS

FIG. 1 is a block diagram schematically illustrating a MEMS resonant sensor according to an exemplary embodiment of the present invention.

FIG. 2 is a block diagram schematically illustrating a MEMS unit according to an exemplary embodiment of the present invention.

FIG. 3 is a flowchart showing a method of controlling the MEMS resonant sensor according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments, which may be included within the spirit and scope of the invention as defined by the appended claims.

Parts that are irrelevant to the description are omitted in order to clearly describe the present invention, and like reference numerals designate like elements throughout the specification.

Throughout this specification and the claims that follow, when it is described that an element is “coupled” to another element, the element may be “directly coupled” to the other element or “electrically coupled” to the other element through a third element. In addition, unless explicitly described to the contrary, the word “comprise” and variations such as “comprises” or “comprising” will be understood to imply the inclusion of stated elements but not the exclusion of any other elements.

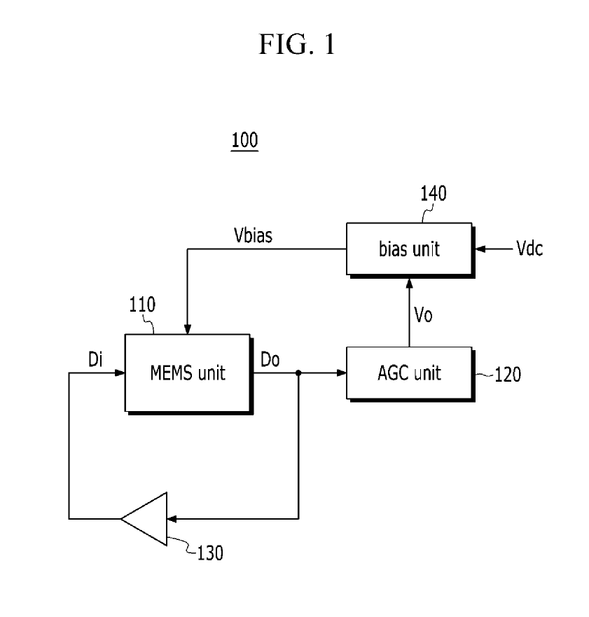

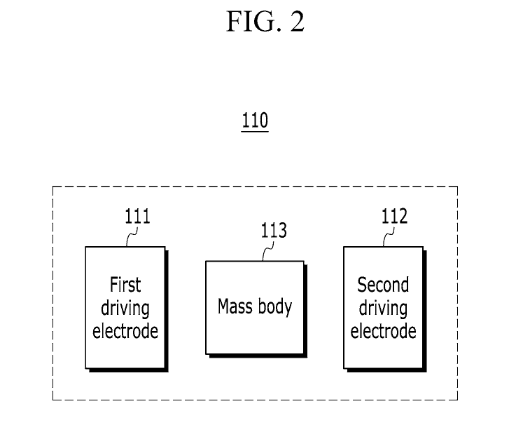

FIG. 1 is a block diagram schematically illustrating the MEMS resonant sensor and FIG. 2 is a block diagram schematically illustrating the MEMS unit according to an exemplary embodiment of the present invention.

Referring to FIG. 1, the MEMS resonant sensor 100 includes a MEMS unit 110, an AGC (automatic gain control) unit 120, a hold amplifier 130, and a bias unit 140.

Referring to FIG. 2, a MEMS unit 110 may include a first driving electrode 111, a second driving electrode 112, and a vibratable mass body 113 between the first driving electrode and the second driving electrode. A sinusoidal driving voltage is applied to the first driving electrode 111 and the second driving electrode 112, and a bias voltage Vbias is applied to the mass body 113. The sinusoidal driving voltage generates an electrostatic force of the mass body 113 between the first driving electrode 111 and the second driving electrode 112, and the mass body 113 vibrates between the first driving electrode 111 and the second driving electrode 112 according to the electrostatic force.

When the mass body 113 vibrates in a first direction between the first driving electrode 111 and the second driving electrode 112, an elastic coefficient of vibration of the first direction is changed by inputting a physical quantity from the outside to the second direction different from the first direction, so that resonant frequency of the MEMS unit 110 is changed. In this case, a size of the physical quantity input is calculated by measuring the change of resonant frequency.

The MEMS unit 110 generates an output signal Do corresponding to a vibration component of the mass body 113.

The AGC unit 120 generates a comparative voltage Vo by automatically controlling a gain of the output signal Do. That is, when the output signal Do is a pulse signal which has amplitude and frequency depending on vibration of the mass body 113, the AGC unit 120 maintains the comparative voltage Vo automatically by controlling the gain of the output signal Do. The comparative voltage Vo is transmitted to the bias unit 140.

The hold amplifier 130 receives the output signal Do, and outputs an input signal Di by amplifying the output signal Do. The input signal Di is input to the MEMS unit 110, and the MEMS unit 110 maintains an output of the output signal Do by using the input signal Di.

The bias unit 140 receives a reference voltage Vdc, and generates a bias voltage Vbias by using the reference voltage Vdc and the comparative voltage Vo. For example, the bias unit 140 may generate a sum or a difference of the reference voltage Vdc and the comparative voltage Vo as the bias voltage Vbias. The bias voltage Vbias is transmitted to the mass body 113 of the MEMS unit 110.

The gain of the AGC unit 120 increases in the case that the mass body 113 vibrates initially and precisely according to mechanical or electrical noise generated naturally from non-vibrated initial condition of the mass body 113. Therefore, a higher bias voltage Vbias is applied to the mass body 113 of the MEMS unit 110. That is, the bias voltage Vbias applied to the mass body 113 of the MEMS unit 110 is adjusted corresponding to the comparative voltage Vo automatically controlling the gain of the output signal Do of the MEMS unit 110, so that the adjusted bias voltage Vbias controls the electrostatic force of the MEMS unit 110. The time that the mass body 113 vibrates with stable amplitude from the initial vibration is reduced considerably according to the controlled electrostatic force of the MEMS unit 110.

In addition, when the amplitude of the mass body 113 is not maintained stably after the vibration of the mass body 113 because of factors such as electrical noise, mechanical noise from the outside, temperature change, and so on, the amplitude of the mass body 113 is stably maintained by controlling the electrostatic force of the MEMS unit 110 according to automatic control of the gain of the AGC unit 120.

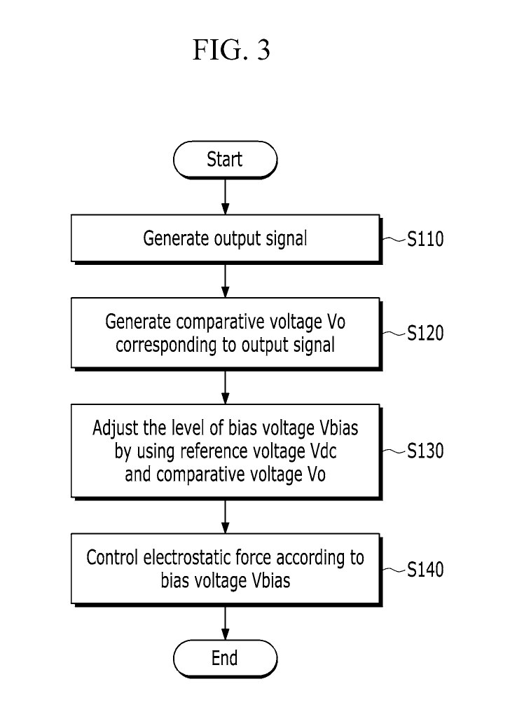

FIG. 3 is a flowchart showing a method of controlling the MEMS resonant sensor according to an exemplary embodiment of the present invention.

Referring to FIG. 3, the MEMS unit 110 vibrates the mass body 113 between the first driving electrode 111 and the second driving electrode 112 by applying the sinusoidal driving voltage to the first driving electrode 111 and the second driving electrode 112 and the bias voltage to the mass body 113, and generates the output signal corresponding to a vibration component of the mass body 113 (S 110). When the mass body 113 vibrates in the first direction between the first driving electrode 111 and the second driving electrode 112, the elastic coefficient of vibration in the first direction is changed by inputting a physical quantity from the outside to the second direction different from the first direction, so that resonant frequency of the MEMS unit 110 which is the vibration component of the mass body 113 is changed. The size of the physical quantity input is calculated by detecting the output signal corresponding to the vibration component of the mass body 113.

The AGC unit 120 generates a comparative voltage Vo corresponding to the output signal Do by automatically controlling a gain of the output signal Do (S120). The output signal Do is a pulse signal which has amplitude and frequency depending on vibration of the mass body 113. The comparative voltage Vo may have a level of voltage corresponding to an envelope characteristic of the output signal Do.

The bias unit 140 adjusts the level of the bias voltage Vbias by using the reference voltage Vdc and the comparative voltage Vo (S130). The bias voltage Vbias may be generated as a sum or a difference of the reference voltage Vdc and the comparative voltage Vo. That is, the bias voltage Vbias applied to the mass body 113 of the MEMS unit 110 is adjusted corresponding to the comparative voltage Vo automatically controlling the gain of the output signal Do of the MEMS unit 110.

The bias voltage Vbias is applied to the mass body 113 of the MEMS unit 110, and the electrostatic force of the MEMS unit 110 is controlled by the bias voltage Vbias (S140). The amplitude of the mass body 113 is stably maintained by controlling the electrostatic force of the MEMS unit 110.

When the amplitude of the mass body 113 is stably maintained and the mass body 113 vibrates in the first direction between the first driving electrode 111 and the second driving electrode 112, an elastic coefficient of vibration in the first direction is changed by inputting a physical quantity from the outside to the second direction different from the first direction, so that resonant frequency of the MEMS unit 110 is changed. In this case, a size of the physical quantity input is calculated by measuring the change of resonant frequency.

The foregoing descriptions of specific exemplary embodiments of the present invention have been presented for purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. A micro-electro-mechanical-system (MEMS) resonant sensor comprising:
a MEMS unit that generates an output signal corresponding to a vibration component of a mass body vibratable between a first driving electrode and a second driving electrode;
an automatic gain control (AGC) unit that generates a comparative voltage by automatically controlling a gain of the output signal of the MEMS unit; and
a bias unit that receives the comparative voltage and a reference voltage and generates a bias voltage using the comparative voltage and the reference voltage,
wherein a sinusoidal driving voltage is applied to the first driving electrode and the second driving electrode, and the bias voltage is applied to the mass body.

2. The MEMS resonant sensor of claim 1, further comprising a hold amplifier generating an input signal that is input to the MEMS unit by amplifying the output signal of the MEMS unit.

3. The MEMS resonant sensor of claim 1, wherein the bias unit generates a sum or a difference of the reference voltage and the comparative voltage as the bias voltage.

4. A method of controlling a MEMS resonant sensor using a mass body vibratable by an electrostatic force between a first driving electrode and a second driving electrode, the method comprising:
generating an output signal corresponding to a vibration component of the mass body;
generating a comparative voltage corresponding to the output signal by automatically controlling a gain of the output signal;
adjusting a level of a bias voltage applied to the mass body by using a reference voltage and the comparative voltage; and
controlling the electrostatic force by applying the adjusted bias voltage to the mass body.

5. The method of claim 4, wherein the generation of the comparative voltage corresponding to the output signal comprises applying a sinusoidal driving voltage to the first driving electrode and the second driving electrode.

6. The method of claim 4, wherein the generation of the comparative voltage corresponding to the output signal by automatically controlling the gain of the output signal comprises generating a sum or a difference of the reference voltage and the comparative voltage as the bias voltage.

7. A method of controlling a MEMS resonant sensor, comprising:
applying a sinusoidal driving voltage to a first driving electrode and a second driving electrode;
applying a bias voltage to a mass body which vibrates in a first direction between the first driving electrode and the second driving electrode by an electrostatic force;
generating an output signal corresponding to a vibration component of the mass body; and
determining a size of a physical quantity input from the outside in a second direction by detecting the output signal,
wherein the applying the bias voltage to the mass body comprises:
generating a comparative voltage corresponding to the output signal by automatically controlling a gain of the output signal;
adjusting a level of the bias voltage applied to the mass body by using a reference voltage and the comparative voltage; and
controlling the electrostatic force by applying the adjusted bias voltage to the mass body.

8. The method of claim 7, wherein the generation of the comparative voltage corresponding to the output signal by automatically controlling the gain of the output signal comprises generating a sum or a difference of the reference voltage and the comparative voltage as the bias voltage.
